(19) United States
(12) Patent Application Publication
(10) Pub. No.: US 2016/0029499 A1
(43) Pub. Date: Jan. 28, 2016

(54) Communication Module

(71) Applicant: Hitachi Metals, Ltd., Tokyo (JP)

(72) Inventor: Yoshinori SUNAGA, Hitachinaka (JP)

(21) Appl. No.: 14/716,089

(22) Filed: May 19, 2015

(30) Foreign Application Priority Data
Jul. 22, 2014 (JP) 2014-148828

(51) Int. Cl. H05K 5/02

(52) U.S. Cl. CPC H05K 5/0221; H05K 5/0286

(57) ABSTRACT

The communication module includes a case including a plug connector which is inserted into/pulled out from a receptacle connector provided on a substrate, a latching hole into/from which a latching piece provided on the substrate can be moved/separated, and movable pieces moved in directions of being brought close to and separating from the latching hole by operations of operating pieces. Each operating direction of the operating pieces is a direction orthogonal to both of an arranging direction of the communication module and other communication module adjacent thereto and an inserting/pulling-out direction of the plug connector. The movable pieces moved in the direction of being brought close to the latching hole by the operations of the operating pieces separate the latching piece from the latching hole.

### CROSS-REFERENCE TO RELATED APPLICATION

The present application claims priority from Japanese Patent Application No. 2014-148828 filed on Jul. 22, 2014, the content of which is hereby incorporated by reference into this application.

### TECHNICAL FIELD OF THE INVENTION

The present invention relates to a communication module used in signal transmission between electronic devices and signal transmission inside an electronic device.

### BACKGROUND OF THE INVENTION

The amount of information handled between electronic devices and the amount of information handled inside an electronic device have increased year by year. With this increase in the amount of information, the number of communication modules to be mounted on the electronic device has also increased, and therefore, it is desired to mount a plurality of communication modules with high density.

Here, a communication module and an electronic device having the communication module mounted thereon may be provided with latching means for fixing the communication module and the electronic device. For example, a substrate (motherboard) of the electronic device is provided with a slot having a latching hole formed therein. Meanwhile, the communication module is provided with a latching protrusion which can be latched with and unlatched from a latching hole formed in the slot included in the electronic device, and an operating unit for operating the latching protrusion. When the communication module is inserted into the slot of the electronic device, the latching protrusion protruding from a case of the communication module is latched with the latching hole formed in the slot. On the other hand, the latching protrusion latched with the latching hole is retracted into the case by the operation of the operating unit so as to be unlatched from the latching hole.

### PRIOR ART DOCUMENT

### Patent Document

Patent Document 1: Japanese Patent Application Laid-Open Publication No. 2007-13102

### SUMMARY OF THE INVENTION

When a plurality of communication modules are mounted with high density, a gap between adjacent communication modules is narrowed, and therefore, there is a risk of impossibility or difficulty in accessing the operating unit provided to each communication module. More particularly, when the operating direction of the operating unit provided to each communication module is parallel to the arranging direction of the communication modules while the plurality of communication modules are arranged with a narrow pitch in parallel to each other, there is a risk of not only the impossibility or difficulty in accessing the operating unit but also impossibility or difficulty in ensuring an operating amount (stroke) of the operating unit.

An object of the present invention is to provide a communication module including a latching protrusion and an operating unit for operating the latching protrusion and being capable of easily accessing the operating unit even in the case of high-density mounting.

A communication module of the present invention is a communication module mounted on a substrate together with a plurality of other communication module. The communication module of the present invention includes: a case provided with a second connector inserted to/pulled out from a first connector provided on the substrate; a latching hole which is provided on the case and to/from which a latching piece provided on the substrate can be inserted/pulled out; an operating piece which is provided on the case and which is operated in a predetermined direction; and a movable piece which is provided on the case and which moves in a direction of being brought close to the latching hole and a direction of separating from the latching hole by operation of the operating piece. The operating direction of the operating piece is a direction orthogonal to both of an arranging direction of the communication module and other communication module adjacent to this communication module and the inserting/pulling-out direction of the first connector. The movable piece moved in the direction of being brought close to the latching hole by the operation of the operating piece separates the latching piece from the latching hole.

In an aspect of the present invention, a pair of the operating pieces and a pair of the movable pieces are provided. When the pair of operating pieces are brought close to each other in the operating direction, the pair of movable pieces are moved in the direction of separating from each other so that each of them is brought close to the latching hole.

In another aspect of the present invention, the pair of operating pieces protrude from a bottom surface of the case provided with the second connector and from a top surface of the case. Also, one of the pair of movable pieces is arranged inside the latching hole formed on a first side surface of the case, and the other of the pair of movable pieces is arranged inside the latching hole formed on a second side surface of the case which faces the first side surface.

In still another aspect of the present invention, the communication module is provided on the substrate and is inserted to/pulled out from a slot accommodating the first connector therein, and the latching piece is provided in periphery of an opening part of the slot.

In still another aspect of the present invention, the operating piece and the movable piece linearly move in parallel to each other.

In still another aspect of the present invention, the operating piece linearly moves, and the movable piece swings.

According to the present invention, a communication module which can easily access the operating unit even in the case of high-density mounting is achieved.

### BRIEF DESCRIPTIONS OF THE DRAWINGS

FIG. 1 is an exploded perspective view showing an example of a structure of an electronic device having a communication module mounted thereon to which the present invention is applied;

FIG. 2 is a perspective view showing an example of the communication module to which the present invention is applied;

FIG. 3 is an enlarged cross-sectional view of the communication module shown in FIG. 2;

FIG. 4 is a partially-enlarged cross-sectional view of the communication module shown in FIG. 2;

FIG. 5 is a perspective view schematically showing a working member;

FIG. 6 is another partially-enlarged cross-sectional view of the communication module shown in FIG. 2;

FIG. 7 is a partially-enlarged cross-sectional view showing another example of the communication module to which the present invention is applied;

FIG. 8 is another partially-enlarged cross-sectional view of the communication module shown in FIG. 7; and

FIG. 9 is a perspective view showing another example of a structure of the electronic device having the communication module mounted thereon to which the present invention is applied.

### DESCRIPTIONS OF THE PREFERRED EMBODIMENTS

An example of embodiments of the communication module of the present invention will be described below. The communication module according to the present embodiment is mounted on an electronic device not shown in the drawing, together with a plurality of other communication modules. Specifically, the communication module according to the present embodiment and other communication modules are each inserted into a slot provided on a substrate (motherboard) included in the electronic device, and is connected to a connector included in the slot. Thus, the structure of the electronic device will be described first, and then, the structure of the communication module according to the present embodiment will be described. Note that the communication module according to the present embodiment and the other communication modules having the same shape and structure as those of the communication module are mounted on the motherboard of the electronic device with high density. However, in the drawings attached to the present specification, the illustration of the other communication modules is omitted.

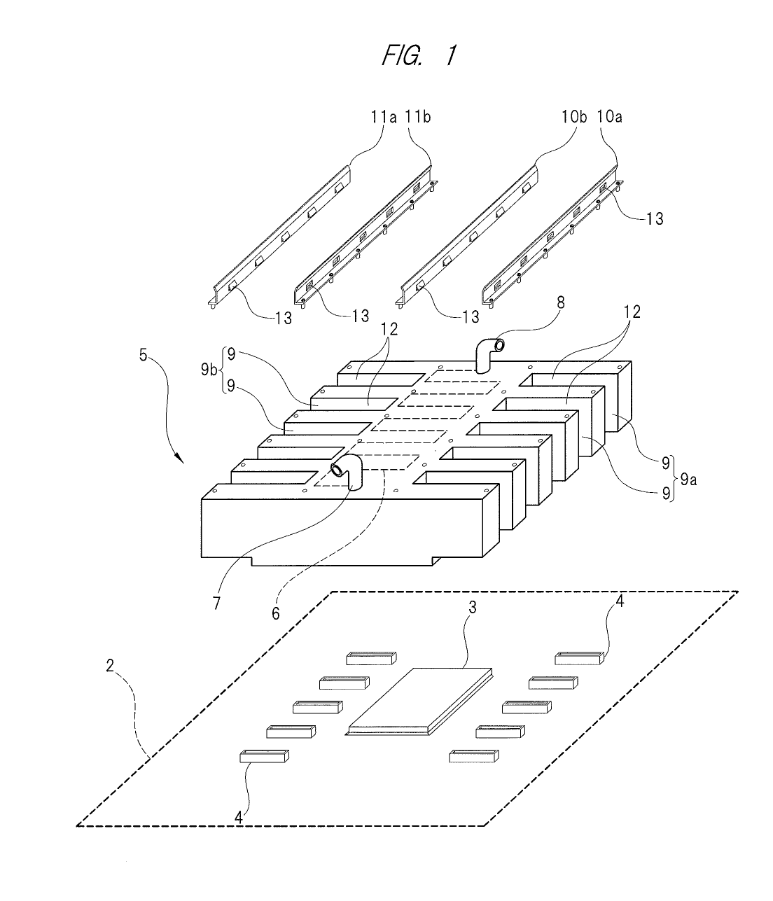

As shown in FIG. 1, a communication semiconductor chip 3 is mounted substantially at the center of a motherboard 2 included in the electronic device. Also, a plurality of first connectors (receptacle connectors 4) are arranged in periphery of the communication semiconductor chip 3. Each of the receptacle connectors 4 is electrically connected to the communication semiconductor chip 3 via a wire, although not shown, formed on the motherboard 2.

Furthermore, a heat sink 5 is overlapped and mounted on the communication semiconductor chip 3 mounted on the motherboard 2, and the top surface of the communication semiconductor chip 3 and the bottom surface of the heat sink 5 are in contact with each other via a thermally conductive sheet not shown. That is, the communication semiconductor chip 3 and the heat sink 5 are thermally connected to each other. A refrigerant passage 6 winding in a zigzag manner is formed inside the heat sink 5, one end of the refrigerant passage 6 communicates with a connection plug 7 formed on the top surface of the heat sink 5, and the other end of the refrigerant passage 6 communicates with another connection plug 8 formed on the top surface of the heat sink 5. A refrigerant supply pipe not shown is connected to the one connection plug 7, and a refrigerant collection pipe not shown is connected to the other connection plug 8. By a pump embedded in the electronic device although not shown, the refrigerant (for example, water) is supplied to the heat sink 5 via the refrigerant supply pipe and the connection plug 7. The refrigerant supplied to the heat sink 5 passes through the refrigerant passage 6, and is collected in the pump via the connection plug 8 and the refrigerant collection pipe. That is, the refrigerant is circulated in the heat sink 5.

Two facing sides of the heat sink 5 are formed in a comb shape so as to avoid the receptacle connectors 4. Specifically, a plurality of slits 9 are formed on one side of the heat sink 5 along the one side, and a plurality of slits 9 are formed on another side of the heat sink 5 along another side. When the heat sink 5 is mounted at a predetermined position on the motherboard 2, each receptacle connector 4 is accommodated inside a predetermined slit 9. That is, while the communication semiconductor chip 3 is covered with the heat sink 5, the receptacle connectors 4 are not covered with the heat sink 5. In other words, a plurality of slots including the receptacle connectors 4 are formed on the motherboard 2. Accordingly, in the following description, each slit 9 formed in the heat sink 5 may be referred to as a “slot 9”. Also, the plurality of slots 9 formed on the right side of the heat sink 5 in FIG. 1 may be collectively referred to as a “right slot line 9a” and the plurality of slots 9 formed on the left side of the heat sink 5 may be collectively referred to as a “left slot line 9b”.

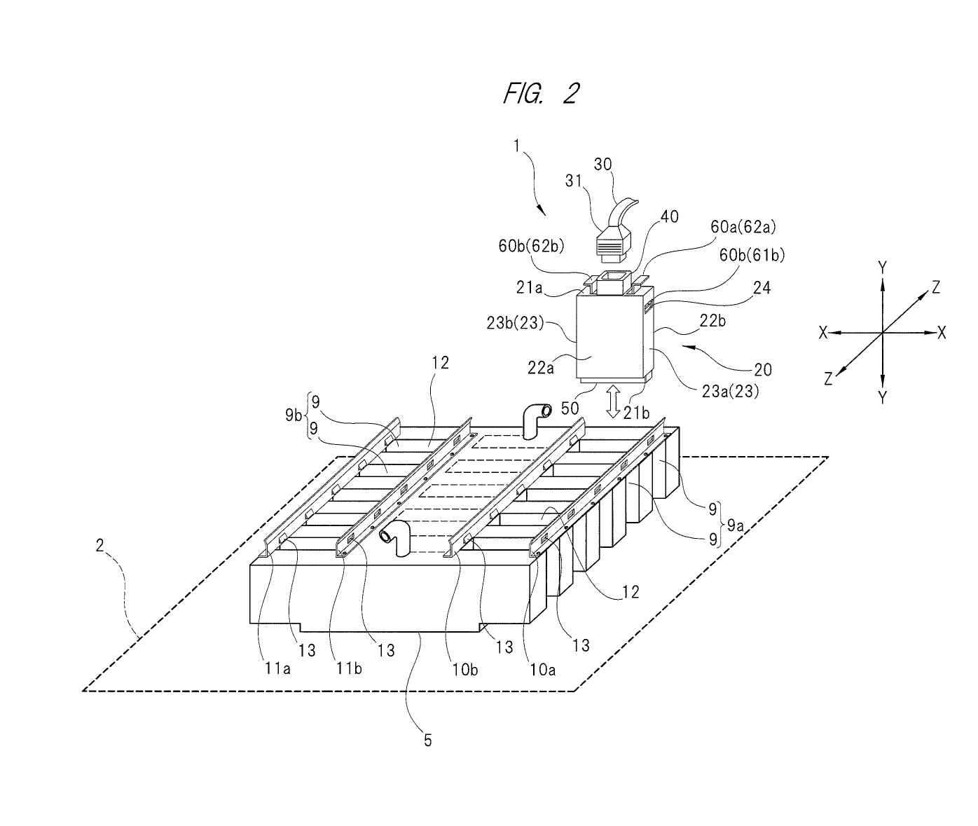

On the top surface of the heat sink 5, a pair of angle members 10a and 10b and another pair of angle members 11a and 11b are arranged. Each of the angle members 10a, 10b, 11a, and 11b is made of metal such as aluminum or stainless, and is screwed onto the top surface of the heat sink 5. Specifically, as shown in FIG. 2, the pair of angle members 10a and 10b are screwed onto both sides of the right slot line 9a, and another pair of angle members 11a and 11b are screwed onto both sides of the left slot line 9b. In other words, the pair of angle members 10a and 10b face each other across an opening part 12 of each slot 9 included in the right slot line 9a, and another pair of angle members 11a and 11b face each other across an opening part 12 of each slot 9 included in the left slot line 9b.

In each of the angle members 10a, 10b, 11a, and 11b, a plurality of latching holes 13 are formed along a longitudinal direction of the angle members, and these latching holes 13 are arranged with the same pitch as those of the slots 9. That is, each of a pair of facing latching pieces 13 and 13 is provided in periphery of an opening part 12 (in the present embodiment, on both sides of the opening part 12 in a width direction) of each slot 9. Each of the pair of latching pieces 13 and 13 is a part of the angle materials 10a, 10b, 11a, and 11b which are bent inward in the width direction of the opening part 12, and has flexibility. Therefore, when each latching piece 13 is pressed outward in the width direction of the opening part 12, it is bent in the same direction. However, when it is unpressurized, it is recovered to an initial state (position) by elastic restoring force. That is, when the pressure force applied outward in the width direction of the opening part 12 is applied onto the facing latching pieces 13 and 13, a facing distance between these latching pieces 13 and 13 increases. On the other hand, when it is unpressurized, the facing distance between the latching pieces 13 and 13 returns to an initial distance.

Next, the communication module according to the present embodiment will be described in detail. As shown in FIG. 2, a communication module 1 is inserted to/pulled out from the slot 9 through the opening part 12 of each slot 9 formed of a part of the heat sink 5.

The communication module 1 has a case 20 formed substantially in a rectangular parallelepiped shape and made of a sheet metal. The case 20 of the communication module 1 has a top surface 21a and a bottom surface 21b facing each other, a front surface 22a and a back surface 22b facing each other, and a first side surface 23a and a second side surface 23b facing each other. In the following description, the first side surface 23a and the second side surface 23b may be collectively referred to as a “side surface 23”. Also, a facing direction of the top surface 21a and the bottom surface 21b is defined as a “height direction”, a facing direction of the first side surface 23a and the second side surface 23b is defined as a “width direction”, and a facing direction of the front surface 22a and the back surface 22b is defined as a “thickness direction”. According to these definitions, the communication module 1 is a thin module with the dimension in the thickness direction smaller than the dimensions in the height direction and the width direction.

The case 20 of the communication module 1 is provided with an optical connecting unit 40 connected with an optical connector 31 attached to an end of an optical fiber cable 30 and provided with a second connector (plug connector 50) inserted to/pulled out from a receptacle connector 4 (FIG. 1). Also, a latching hole 24 is provided on each of a first side surface 23a and a second side surface 23b of the case 20. The case 20 is provided with a movable piece 61b which moves forward into/backward from the case 20 through the latching hole 24 formed on the first side surface 23a and with a working member 60b including an operating piece 62b for operating the movable piece 61b. Also, the case 20 is provided with a movable piece 61a which moves forward into/backward from the case 20 through the latching hole 24 formed on the second side surface 23b and with a working member 60a including an operating piece 62a for operating the movable piece 61a. Incidentally, FIG. 2 does not show the latching hole 24 formed on the second side surface 23b and the movable piece 61a.

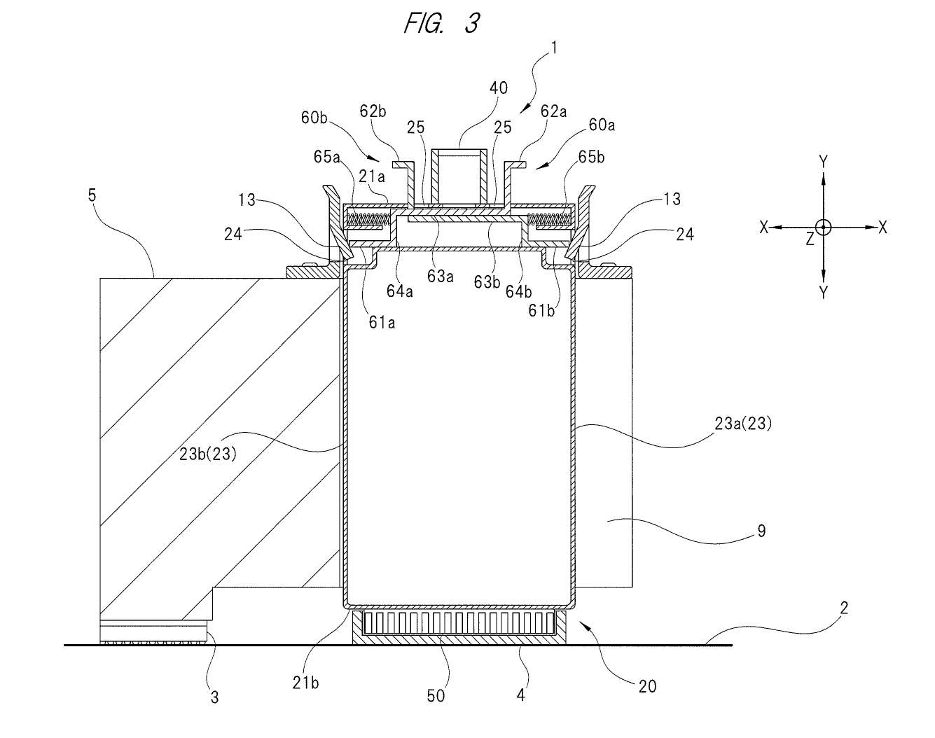

As shown in FIG. 3, the plug connector 50 is an edge connector (card edge) protruding from the bottom surface 21b of the case 20. On the other hand, the optical connecting unit 40 protrudes from the top surface 21a of the case 20 facing the bottom surface 21b. Also, one of the latching protrusions 61 protrudes from the first side surface 23a of the case 20, and the other of the latching protrusions 61 protrudes from the second side surface 23b of the case 20 facing the first side surface 23a. Furthermore, the pair of operating units 62 and 62 protrude from the top surface 21a of the case 20, and face each other across the optical connecting unit 40. Note that various elements required for achieving an optical communication function and other functions are accommodated inside the case 20 although not shown in FIG. 3. For example, at least a light-emitting element and a driving element for driving the light-emitting element are accommodated inside the case 20.

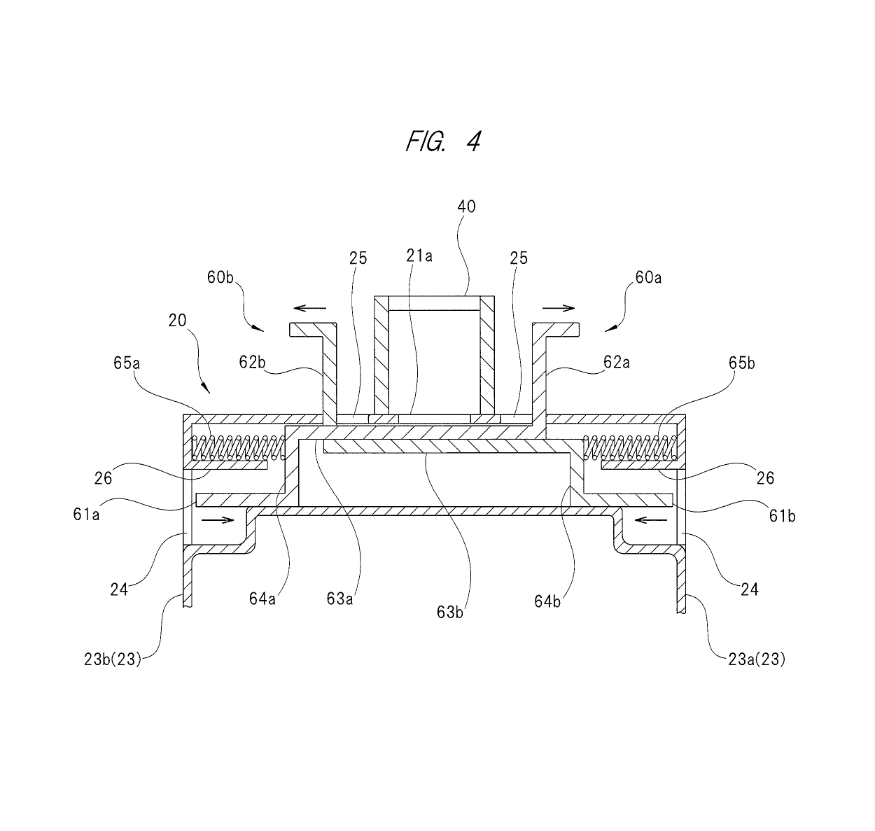

As shown in FIG. 4, in addition to the movable piece 61a and the operating piece 62a, the working member 60a includes: a horizontal part 63a which is in parallel to a top surface 21a of the case 20; and a vertical part 64a extending from a tip of the horizontal part 63a toward a bottom surface 21b (FIG. 3) of the case 20. The movable piece 61a of the working member 60a is arranged inside the latching hole 24 formed on the second side surface 23b of the case 20. The operating piece 62a of the working member 60a protrudes upward from the opening part 25 formed on the top surface 21a of the case 20, and is operated in a predetermined direction.

Similarly, in addition to the movable piece 61b and the operating piece 62b, the working member 60b includes: a horizontal part 63b which is in parallel to the top surface 21a of the case 20; and a vertical part 64b extending from a tip of the horizontal part 63b toward the bottom surface 21b (FIG. 3) of the case 20. The movable piece 61b of the working member 60b is arranged inside the latching hole 24 formed on the first side surface 23a of the case 20. The operating piece 62b of the working member 60b protrudes upward from the opening part 25 formed on the top surface 21a of the case 20, and is operated in a predetermined direction.

Incidentally, the movable piece 61a, the operating piece 62a, the horizontal part 63a, and the vertical part 64a included in the working member 60a are integrally formed. Specifically, each of the movable piece 61a, the operating piece 62a, the horizontal part 63a, and the vertical part 64a is apart of a belt-shaped steel metal which is bent so as to be stepwise. Also, the movable piece 61b, the operating piece 62b, the horizontal part 63b, and the vertical part 64b included in the working member 60b are integrally formed. Specifically, each of the movable piece 61b, the operating piece 62b, the horizontal part 63b, and the vertical part 64b is a part of a belt-shaped steel metal which is bent so as to be stepwise. Accordingly, in the following explanation, the movable piece 61a, the operating piece 62a, the horizontal part 63a, and the vertical part 64a are collectively called “working member 60a”, and the movable piece 61b, the operating piece 62b, the horizontal part 63b, and the vertical part 64b are collectively called “working member 60b”.

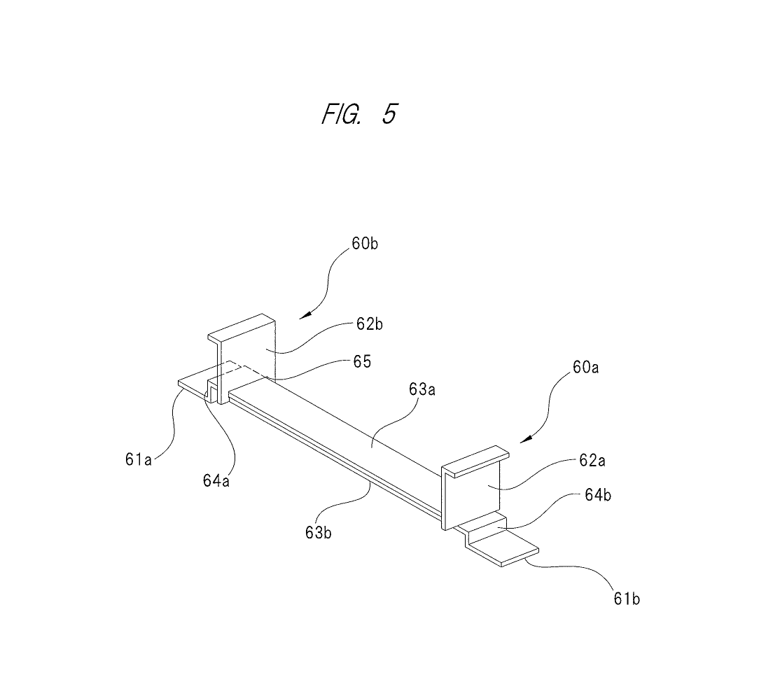

As shown in FIG. 4, the working member 60a and the working member 60b are overlapped and paired with each other. Specifically, the horizontal part 63a of the working member 60a is overlapped on the horizontal part 63b of the working member 60b. Further, as shown in FIG. 5, a slit 65 is formed below the operating piece 62b of the working member 60b, and the horizontal part 63a of the working member 60a protrudes from back of the operating piece 62b of the working member 60b through the slit 65. Also, the horizontal part 63b of the working member 60b protrudes from back of the operating piece 62a through a part below the operating piece 62a of the working member 60a. Therefore, as shown in FIG. 4, while the movable piece 61a of the working member 60a is positioned on a left side of the optical connecting unit 40, the operating piece 62a is positioned on a right side of the optical connecting unit 40. Also, while the movable piece 61b of the working member 60b is positioned on a right side of the optical connecting unit 40, the operating piece 62b is positioned on a left side of the optical connecting unit 40. Note that FIG. 5 schematically shows the working members 60a and 60b. Practically, each of the horizontal parts 63a and 63b of the working members 60a and 60b has such a shape as going around the optical connecting part 40 shown in FIG. 3 or others.

As shown in FIG. 4, two elastic members (coil springs 65a and 65b) are accommodated inside the case 20. One coil spring 65a is arranged between the working member 60a and the second side surface 23b, and the other coil spring 65b is arranged between the working member 60b and the first side surface 23a. Specifically, one end of the coil spring 65a abuts on an outer surface of the vertical part 64a of the working member 60a, and the other end thereof abuts on an inner surface of the second side surface 23b. Also, one end of the coil spring 65b abuts on an outer surface of the vertical part 64b of the working member 60b, and the other end thereof abuts on an inner surface of the first side surface 23a.

The working member 60a is always pressed in a right direction by the coil spring 65a, and the working member 60b is always pressed in a left direction by the coil spring 65b. Incidentally, since each of the operating pieces 62a and 62b of the working members 60a and 60b abuts on the inner surface of the opening part 25, the working member 60a does not move to the right side further than the position shown in FIG. 4, and the working member 60b does not move to the left side further than the position shown in FIG. 4. That is, the positions shown in FIG. 4 are initial positions of the working members 60a and 60b. When the working members 60a and 60b are at the initial positions, a distance between the operating piece 62a and the operating piece 62b facing each other across the optical connecting part 40 is maximized, and a distance between the movable piece 61a and the movable piece 61b is minimized. That is, when the working members 60a and 60b are at the initial positions, the movable piece 61a and the movable piece 62b are the closest to each other, and each of them are positioned backward into the case 20. In other words, when the working members 60a and 60b are at the initial positions, the movable piece 61a and the movable piece 62b are evacuated into the case 20.

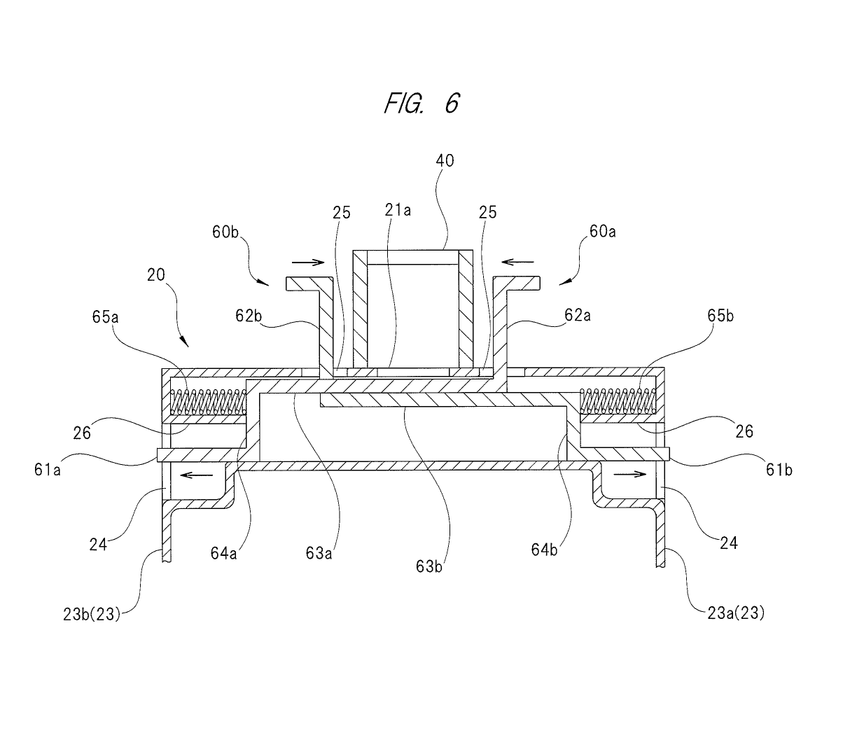

On the other hand, as shown in FIG. 6, when the operating pieces 62a and 62b are operated in a predetermined direction (arrow direction), the movable pieces 61a and 61b are moved toward the outside of the case 20 in opposite directions to each other. Specifically, each of the operating piece 62a of the working member 60a and the operating piece 62b of the working member 60b is pressed inward. Then, the working member 60a is moved in the left direction against the pressing of the coil spring 65a, and the working member 60b is moved in the right direction against the pressing of the coil spring 65b. That is, the working member 60a and the working member 60b slide in opposite directions to each other. In other words, when the operating piece 62a and the operating piece 62b are brought close to each other, the movable piece 61a and the movable piece 61b are separated from each other. In still other words, a distance between the movable piece 61a and the movable piece 61b is increased by decrease in a distance between the operating piece 62a and the operating piece 62b.

The working member 60a can move in the left direction until the outer surface of the vertical part 64a abuts on a rib 26 on which the coil spring 65a is placed. Also, the working member 60b can move in the right direction until the outer surface of the vertical part 64b abuts on a rib 26 on which the coil spring 65b is placed. That is, as shown in FIG. 6, when the vertical parts 64a and 64b of the working members 60a and 60b abut on the ribs 26 and 26, respectively, the distance between the operating piece 62a and the operating piece 62b is minimized, and the distance between the movable piece 61a and the movable piece 61b is maximized. In other words, the movable piece 61a and the movable piece 61b are most separated from each other, so that each of them moves outward (protrude from) the case 20.

With reference to FIG. 2 and FIG. 3, a process of inserting/pulling-out of the communication module 1 into/from the electronic device will be described. First, a process of inserting the communication module 1 into the slot 9 for connection to the receptacle connector 4 will be described. The shown communication module 1 is inserted from above the sheets of FIG. 2 and FIG. 3 into the slot 9, and is connected to the receptacle connector 4 on the bottom of the slot 9. That is, an upside/downside direction (Y direction) on the sheets in FIG. 2 and FIG. 3 is an inserting/pulling-out direction of the plug connector 50 into/from the receptacle connector 4.

Into another slot 9 adjacent to the slit 9 to which the communication module 1 has been inserted, another communication module is inserted. Furthermore, into still another slot 9 adjacent to the slot 9 to which another communication module has been inserted, still another communication module is inserted. That is, the arranging direction of the communication module 1 shown in the drawings and other communication modules adjacent to this communication module is a forward/backward direction (Z direction) on the sheets in FIG. 2 and FIG. 3. This direction matches the arranging direction of the slots 9 and also the thickness direction of the communication module 1.

Here, a pair of latching pieces 13 and 13 are arranged on both sides of the opening part 12 of each slot 9 in a width direction. Further, when pressing force is not applied to the pair of latching pieces 13 and 13, a facing distance between both tips of these latching pieces 13 and 13 is narrower than a dimension of the case 20 of the communication module 1 in the width direction. Therefore, each of the pair of latching pieces 13 and 13 abuts on the case 20 at the beginning of the course of insertion of the communication module 1 into the slot 9, so that the insertion of the communication module 1 into the slot 9 is temporarily restricted.

However, when the communication module 1 is more strongly pressed downward, each of the latching pieces 13 and 13 is pressed toward the outside of the opening part 12 in the width direction. As a result, each of the latching pieces 13 and 13 is bent outward, and the facing direction between the latching pieces 13 and 13 is increased. Then, the restriction of the insertion of the communication module 1 is released, so that the insertion of the communication module 1 into the slot 9 is restarted. Then, the latching pieces 13 and 13 are pressed against the first side surface 23a and the second side surface 23b of the case 20 by the elastic restoring forces themselves so as to be swung on these side surfaces 23, respectively.

Then, when the latching holes 24 and 24 formed in the side surface 23 of the case 20 are lowered down to the positions of the latching pieces 13 and 13, the latching pieces 13 and 13 are unpressurized. Then, as shown in FIG. 3, the latching pieces 13 and 13 move into the latching holes 24 and 24. That is, the latching pieces 13 and 13 are latched with the communication module 1, so that the communication module 1 cannot be pulled out from the slot 9.

Next, a process of disconnecting the receptacle connector 4 from the plug connector 50 and pulling out the communication module 1 from the slot 9 will be described. The operating pieces 62a and 62b of the working members 60a and 60b shown in FIG. 3 are each operated toward the inside of the case 20. That is, the operating pieces 62a and 62b are brought close to each other. In other words, the operating pieces 62a and 62b are brought close to the optical connecting unit 40. The above-described operation of the operating pieces 62a and 62b is performed by, for example, pinching the operating pieces 62a and 62b by the index finger and the thumb.

When each of the operating pieces 62a and 62b is operated as described above, the working member 60a moves in the left direction against pressing of the coil spring 65a, and the working member 60b moves in the right direction against pressing of the coil spring 65b. That is, while the movable piece 61a of the working member 60a is moved in the left direction by the operation of the operating piece 62a so as to be brought close to the latching hole 24, the movable piece 61b of the working member 60b is moved in the right direction by the operation of the operating piece 62b so as to be brought close to the latching hole 24. In other words, the movable piece 61a of the working member 60a is moved in the direction of being brought close to the latching hole 24 by the operation of the operating piece 62a, and the movable piece 61b of the working member 60b is moved in the direction of being brought close to the latching hole 24 by the operation of the operating piece 62b.

When the movable pieces 61a and 61b are brought close to the latching holes 24 and 24 by the operations of the operating pieces 62a and 62b, the latching pieces 13 and 13 which have entered the latching holes 24 and 24 are pushed by the movable pieces 61a and 61b and are separated (pushed out) from the latching holes 24 and 24, so that the latching pieces 13 and 13 are unlatched from the communication module 1. Therefore, when the communication module 1 is pulled up while pinching the operating pieces 62a and 62b, the plug connector 50 is pulled and taken out from the receptacle connector 4, so that the communication module 1 is pulled out from the slot 9.

Note that, when the operations of the operating pieces 62a and 62b are released, while the working member 60a is moved in the right direction by the pressing of the coil spring 65a so that the movable piece 61a is separated from the latching hole 24, the working member 60b is moved in the left direction by the pressing of the coil spring 65b so that the movable piece 61b is separated from the latching hole 24.

As described above, the operating pieces 62a and 62b and the movable pieces 61a and 61b according to the present embodiment are linearly moved. Also, the movement directions of both of them are in parallel to each other. That is, in the present embodiment, the operating pieces 62a and 62b and the movable pieces 61a and 61b are linearly moved in parallel to each other.

Also, a right/left direction (X direction) on the sheets in FIG. 2 and FIG. 3 is an operating direction of the operating pieces 62a and 62b, and this direction is a direction orthogonal to both of the inserting/pulling-out direction (Y direction) of the plug connector 50 and the arranging direction (Z direction) of the communication module 1. That is, the operating direction of each of the operating pieces 62a and 62b is orthogonal to the arranging direction (Z direction) of the communication module 1 and other communication modules adjacent thereto. Therefore, even if many communication modules are arranged in parallel to each other with a small pitch and the gap between the communication module 1 and other communication module adjacent thereto is narrow, it is neither difficult nor impossible to access the operating pieces 62a and 62b, and it is neither difficult nor impossible to ensure the operating amount (stroke) of each of the operating pieces 62a and 62b.

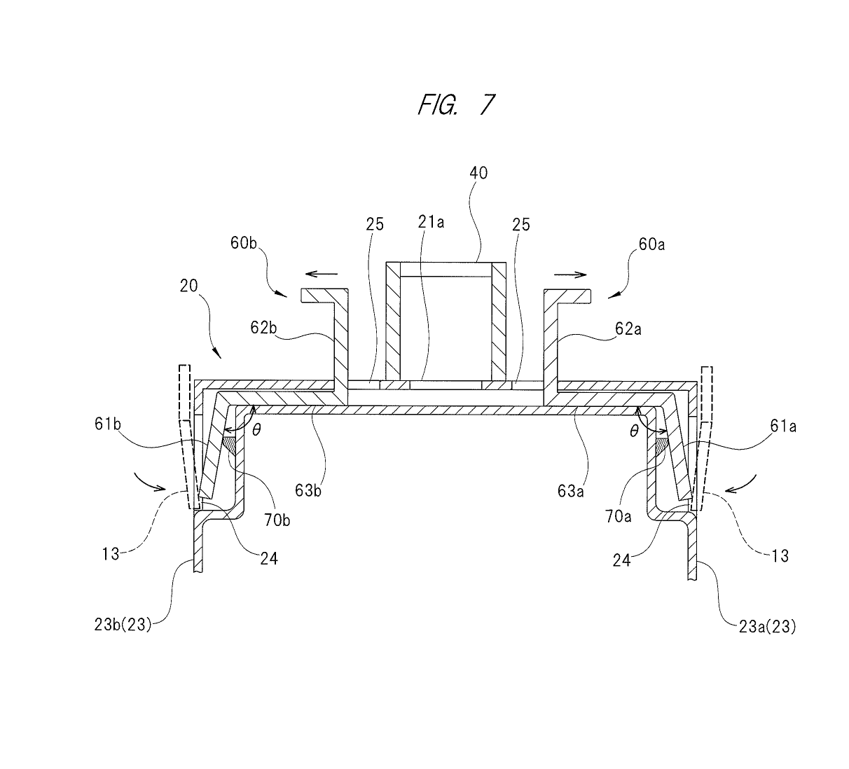

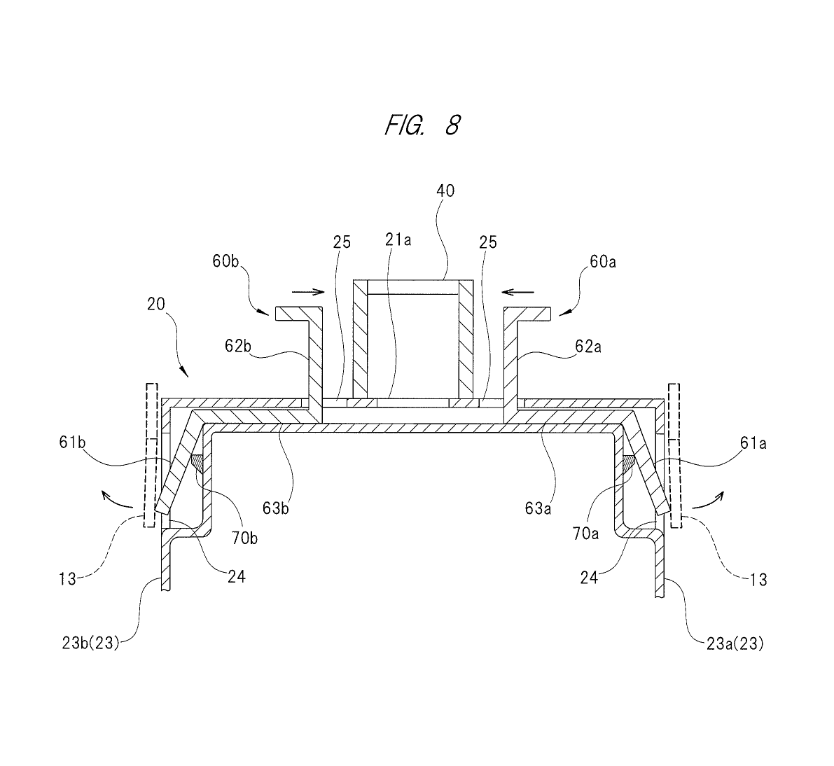

The present invention is not limited to the foregoing embodiment, and various modifications and alterations can be made within the scope of the present invention. For example, the structures of the working members 60a and 60b are not limited to the above-described structures. FIGS. 7 and 8 show one of modification examples of the working members 60a and 60b. The working members 60a and 60b shown in FIGS. 7 and 8 are made of a bent steel metal. The working members 60a and 60b include horizontal parts 63a and 63b in parallel to the top surface 21a of the case 20, operating pieces 62a and 62b extending upward from one ends of the horizontal parts 63a and 63b, and movable pieces 61a and 61b extending downward from the other ends of the horizontal parts 63a and 63b, respectively. That is, the operating pieces 62a and 62b are bent upward from the horizontal parts 63a and 63b, and the movable pieces 61a and 61b are bent downward from the horizontal parts 63a and 63b.

In the embodiment using the working members 60a and 60b having the above-described structures, stoppers 70a and 70b which abut on rear surfaces of the movable pieces 61a and 61b, respectively, are provided inside the case 20.

As shown in FIG. 8, when the operating pieces 62a and 62b are brought close to each other, each of the movable pieces 61a and 61b whose movements are restricted by the stoppers 70a and 70b is bent outward. In other words, the movable piece 61a swings outward while taking a boundary (folding point) between the movable piece 61a and the horizontal part 63a as a pivot point so as to be brought close to the latching hole 24. On the other hand, the movable piece 61b swings outward while taking a boundary (folding point) between the movable piece 61b and the horizontal part 63b as a pivot point so as to be brought close to the latching hole 24.

When the movable pieces 61a and 61b are swung by the operations of the operating pieces 62a and 62b as described above, the latching pieces 13 and 13 which have entered the latching holes 24 and 24 are pushed by the movable pieces 61a and 61b and are separated (pushed out) from the latching holes 24 and 24, so that the latching pieces 13 and 13 are unlatched from the communication module 1.

Note that, when the operations of the operating pieces 62a and 62b are released, the movable pieces 61a and 61b are moved in a direction of separating from the latching holes 24 and 24 by the elastic restoring forces themselves, and are returned to the initial state (state shown in FIG. 7).

As described above, while the operating pieces 62a and 62b shown in FIGS. 7 and 8 linearly move, the movable pieces 61a and 61b swing. Note that it is preferred to set each bent angle of the movable pieces 61a and 61b with respect to the horizontal parts 63a and 63b to be larger than 90 degrees in order to easily swing the movable pieces 61a and 61b as described above, that is, in order to easily bend the movable pieces 61a and 61b as described above. That is, it is preferred to set an angle θ shown in FIG. 7 to be larger than 90 degrees.

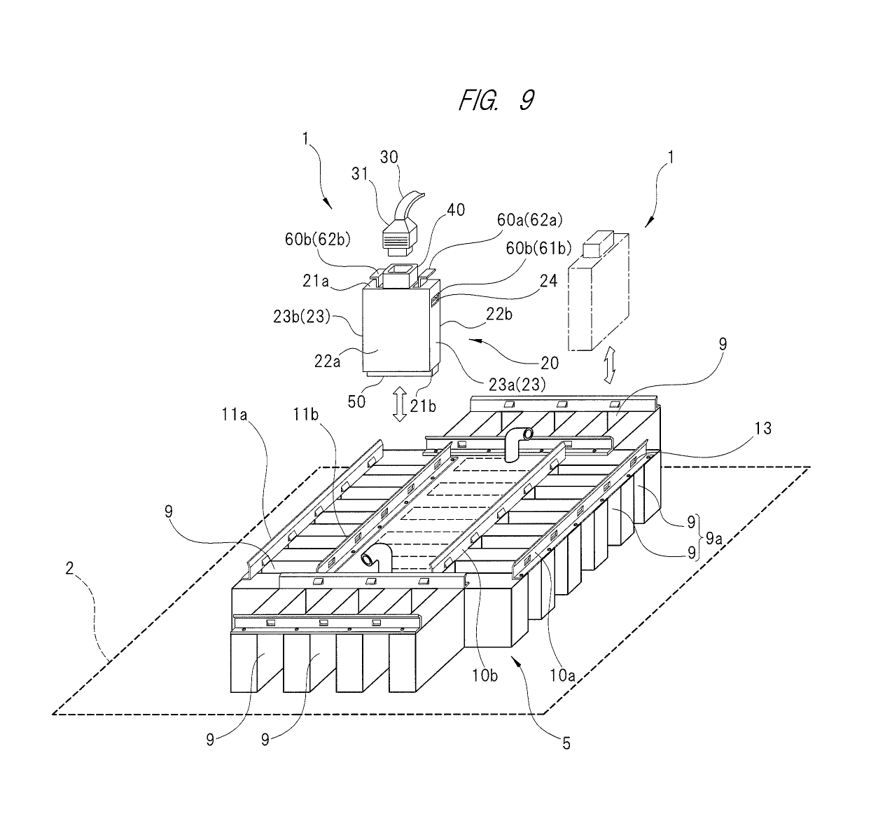

As shown in FIG. 9, the invention has another embodiment in which slots 9 are formed in all sides of the heat sink 5, and the communication module 1 is inserted into each slot 9. Note that structures identical to the structures already described above are denoted by the same reference symbols in FIG. 9, and the repetitive description thereof is omitted. Still further, the invention has still another embodiment in which slots 9 are formed in three sides of the heat sink 5. Still further, the communication module may be inserted into only one/some of the slots included in the electronic device, and the remaining slots may be vacant slots. Incidentally, the invention has still another embodiment in which slots are made of a member different from that of the heat sink. Still further, slots are not indispensable constituent elements of the present invention. For example, the latching pieces may be provided on the substrate by mounting the angle members or others directly on the substrate. That is, the latching pieces may be directly provided on the substrate, or may be provided on any member (for example, the heat sink 5 in the above-described embodiment) mounted on the substrate. Also, the latching pieces may be provided inside the slot. Further, the independent angle members each of which has the latching piece may be arranged for each slot.

The invention has still another embodiment in which the first connector provided on the motherboard is a plug connector and the second connector included in the communication module is a receptacle connector.

In place of the light-emitting element and the driving element, a light-receiving element and an amplifying element may be accommodated inside the case. Furthermore, in addition to the light-emitting element and the driving element, a light-receiving element and an amplifying element may be accommodated inside the case. Still further, the present invention can be applied to not only an optical communication module but also an electrical communication module. Even when the present invention is applied to an electrical communication module, operations and effects similar to those described above can be obtained. In the electrical communication module to which the present invention is applied, an electrical connecting unit is provided in place of the optical connecting unit 40 shown in FIG. 3 or others, and an electrical communication cable is connected to this electrical connecting unit. Also, various elements required for achieving an electrical communication function and other functions are accommodated inside the case.

1. A communication module mounted on a substrate together with a plurality of other communication modules, comprising:
a case including a second connector which is inserted into/pulled out from a first connector provided on the substrate;
a latching hole which is provided in the case and into/from which a latching piece provided on the substrate can be moved/separated;
an operating piece which is provided in the case and which is operated in a predetermined direction; and
a movable piece which is provided in the case and which is moved in a direction of being brought close to the latching hole and a direction of separating from the latching hole by operation of the operating piece,
wherein an operating direction of the operating piece is a direction orthogonal to both of an arranging direction of the communication module and other communication module adjacent to the communication module and an inserting/pulling-out direction of the first connector, and
the movable piece which is moved in the direction of being brought close to the latching hole by the operation of the operating piece separates the latching piece from the latching hole.

2. The communication module according to claim 1, further comprising
a pair of the operating pieces and a pair of the movable pieces,
wherein, when the pair of operating pieces are brought close to each other along the operating direction, each of the pair of movable pieces moves in a direction of separating from each other so as to be brought close to the latching hole.

3. The communication module according to claim 2,
wherein the pair of operating pieces protrude from a top surface of the case which is opposite to a bottom surface of the case provided with the second connector, and
one of the pair of movable pieces is arranged inside the latching hole formed in a first side surface of the case, and the other of the pair of movable pieces is arranged inside the latching hole formed in a second side surface of the case facing the first side surface.

4. The communication module according to claim 1,
wherein the communication module is inserted into/pulled out from a slot provided on the substrate and included in the first connector, and
the latching piece is provided in periphery of an opening part of the slot.

5. The communication module according to claim 1,
wherein the operating piece and the movable piece linearly move in parallel to each other.

6. The communication module according to claim 1,
wherein the operating piece linearly moves, and the movable piece swings.
